(19) United States
(12) Patent Application Publication
(10) Pub. No.: US 2014/0131656 A1
(43) Pub. Date: May 15, 2014

(54) LIGHT EMITTING DIODE CHIP AND METHOD FOR MANUFACTURING THE SAME

(71) Applicant: ADVANCED OPTOELECTRONIC TECHNOLOGY, INC., HSINCHU HSIEN (TW)

(72) Inventors: YA-WEN LIN, Hukou (TW); CHING-HSUEH CHIU, Hukou (TW); PO-MIN TU, Hukou (TW); SHIH-CHENG HUANG, Hukou (TW)

(73) Assignee: ADVANCED OPTOELECTRONIC TECHNOLOGY, INC., Hsinchu Hsien (TW)

(21) Appl. No.: 14/014,381

(22) Filed: Aug. 30, 2013

(30) Foreign Application Priority Data
Nov. 13, 2012 (CN) 2012104530991

(51) Int. Cl. H01L 33/32; H01L 33/00

(52) U.S. Cl. CPC H01L 33/32; H01L 33/0075; Y10S 977/742; Y10S 977/842; Y10S 977/95; B82Y 40/00
USPC 257/13; 438/46; 977/742; 977/842; 977/950

(57) ABSTRACT

A light emitting diode chip includes a sapphire substrate and a plurality of carbon nano-tubes arranged on an upper surface of the sapphire substrate. Gaps are formed between two adjacent carbon nano-tubes to expose parts of the upper surface of the sapphire substrate. An un-doped GaN layer is formed on the exposed parts of the upper surface of the sapphire substrate and covers the carbon nano-tubes. An n-type GaN layer, an active layer and a p-type GaN layer are formed on the un-doped GaN layer in sequence. A method for manufacturing the light emitting diode chip is also provided.

### BACKGROUND

1. Technical Field

The disclosure generally relates to a light emitting diode (LED) chip, and a method for manufacturing the LED chip, wherein the LED chip has cabon nano-tubes on a substrate thereof for improving the epitaxial quality and the light extraction efficiency of the LED chip.

2. Description of Related Art

In recent years, due to excellent light quality and high luminous efficiency, light emitting diodes (LEDs) have increasingly been used as substitutes for incandescent bulbs, compact fluorescent lamps and fluorescent tubes as light sources of illumination devices.

In epitaxial growth of an LED chip, one problem is how to reduce lattice defects in semiconductor layers. One way to reduce the lattice defects is to provide a pattered sapphire substrate. The semiconductor layers are laterally grown from the pattered sapphire substrate to reduce the lattice defects. However, since the sapphire substrate is hard to be etched, the pattern sapphire substrate will has a poor quality, which affects the epitaxial quality of the semiconductor layers formed on the patterned sapphire substrate. The inferior epitaxial quality affects the light extraction efficiency of the LED chip.

What is needed, therefore, is an LED chip to overcome the above described disadvantages.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, like reference numerals designate corresponding parts throughout the several views.

FIG. 1 is a cross-sectional view showing an LED chip in accordance with an embodiment of the present disclosure.

FIG. 2 shows full width at half maximum (FWHM) values of an XRD pattern of co-scan in (1-100) plane of a GaN layer grown from (002) plane of a sapphire substrate.

FIG. 3 shows full width at half maximum (FWHM) values of an XRD pattern of co-scan in (11-20) plane of a GaN layer grown from (002) plane of a sapphire substrate.

FIG. 4 shows full width at half maximum (FWHM) values of an XRD pattern of co-scan in (1-100) plane of a GaN layer grown from (102) plane of a sapphire substrate.

FIG. 5 shows full width at half maximum (FWHM) values of an XRD pattern of co-scan in (11-20) plane of a GaN layer grown from (102) plane of a sapphire substrate.

FIG. 6 is a diagraph showing a relationship between a light intensity and a current in the LED chip in FIG. 1.

### DETAILED DESCRIPTION

An embodiment of an LED epi layer and a method for growing the LED epi layer will now be described in detail below and with reference to the drawings.

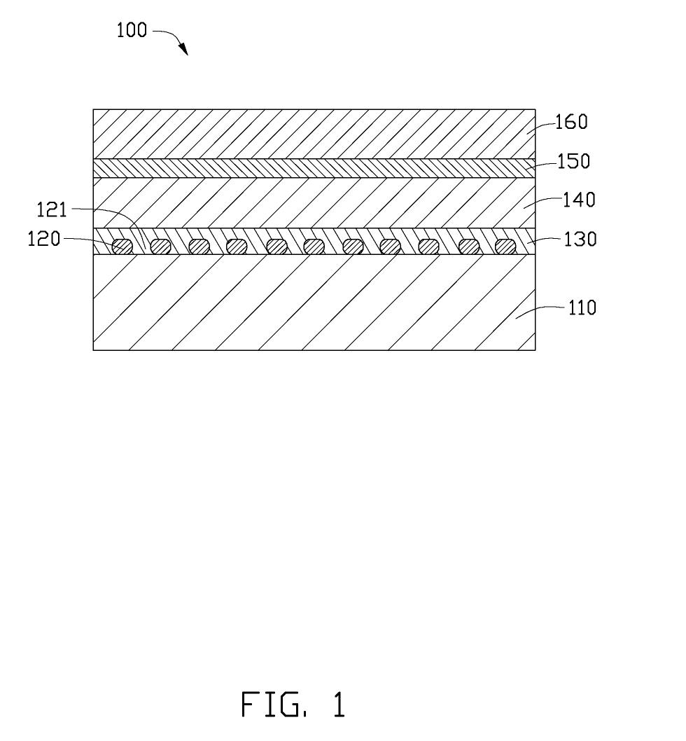

Referring to FIG. 1, an LED epi layer 100 in accordance with an embodiment is provided. The LED epi layer 100 includes a sapphire substrate 110, a plurality of carbon nano-tubes 120, an un-doped GaN layer 130, an n-type GaN layer 140, an active layer 150 and a p-type GaN layer 160. The carbon nano-tubes 120 are arranged on an upper surface of the sapphire substrate 110. Gaps 121 are formed between two adjacent carbon nano-tubes 120 to expose parts of the sapphire substrate 110. In this embodiment, diameters of the carbon nano-tubes 120 each are in a range from 15 nanometers (nm) to 30 nm. The carbon nano-tubes 120 are parallel to each other and also paralleled to the upper surface of the sapphire substrate 111. The un-doped GaN layer 130 is formed on the exposing parts of the upper surface of the sapphire substrate 110, fills up the gaps 121 between the carbon nano-tubes 120 and covers the carbon nano-tubes 120. The n-type GaN layer 140, the active layer 150 and the p-type GaN layer 160 are formed on the un-doped GaN layer 130 in sequence. Preferably, the active layer 150 is a multiple quantum wells (MQW) structure.

In the LED epi layer 100 described above, the carbon nano-tubes 120 are located on and cover the upper surface of the sapphire substrate 110. During epitaxial growth of the un-doped GaN layer 130 on the sapphire substrate 110, the carbon nano-tubes 120 will act as a patterned layer. That is, the un-doped GaN layer 130 firstly grows from the exposed parts of the upper surface of the sapphire substrate 110, fills up the gaps 121 between the carbon nano-tubes 120, and then laterally grows to cover the carbon nano-tubes 120. The lateral growth of the un-doped GaN layer 130 will reduce the lattice defects in the un-doped GaN layer 130, thereby improving epitaxial quality of the n-type GaN layer 140, the active layer 150 and the p-type GaN layer 160 formed on the un-doped GaN layer 130.

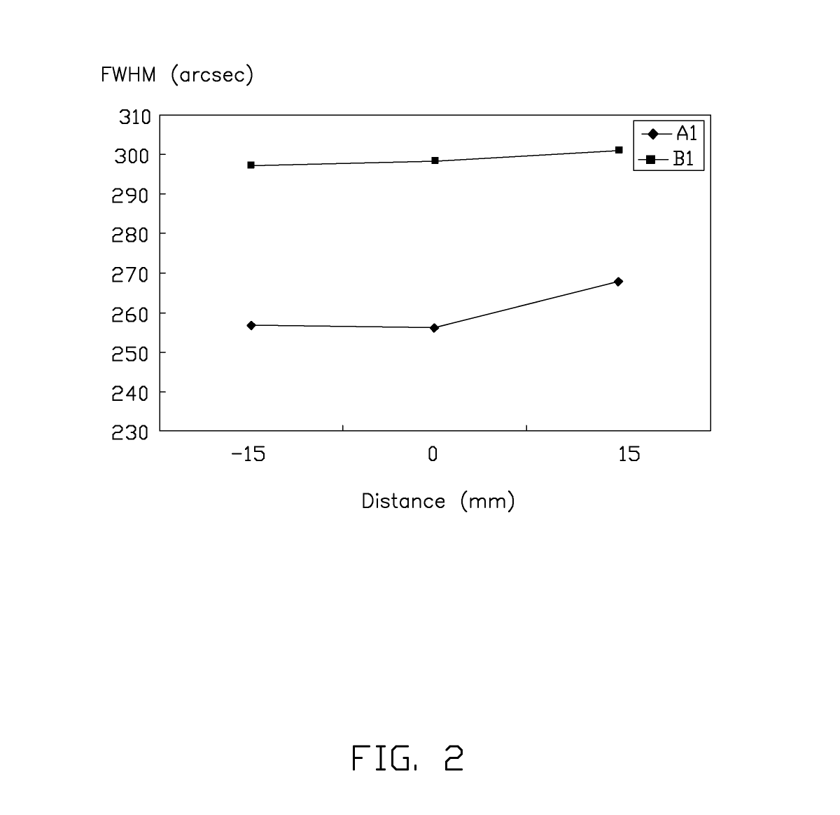

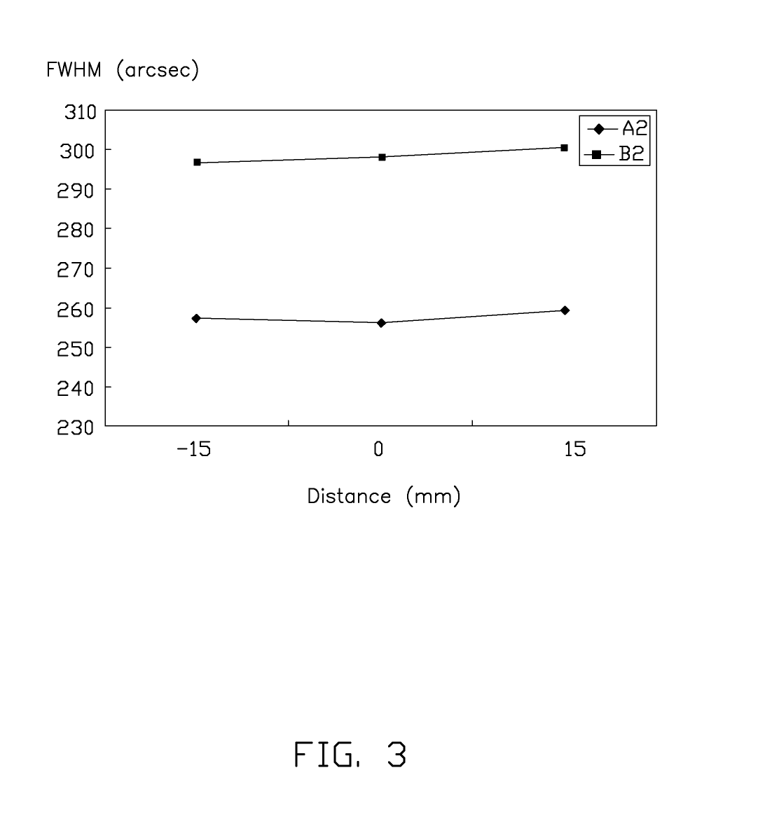

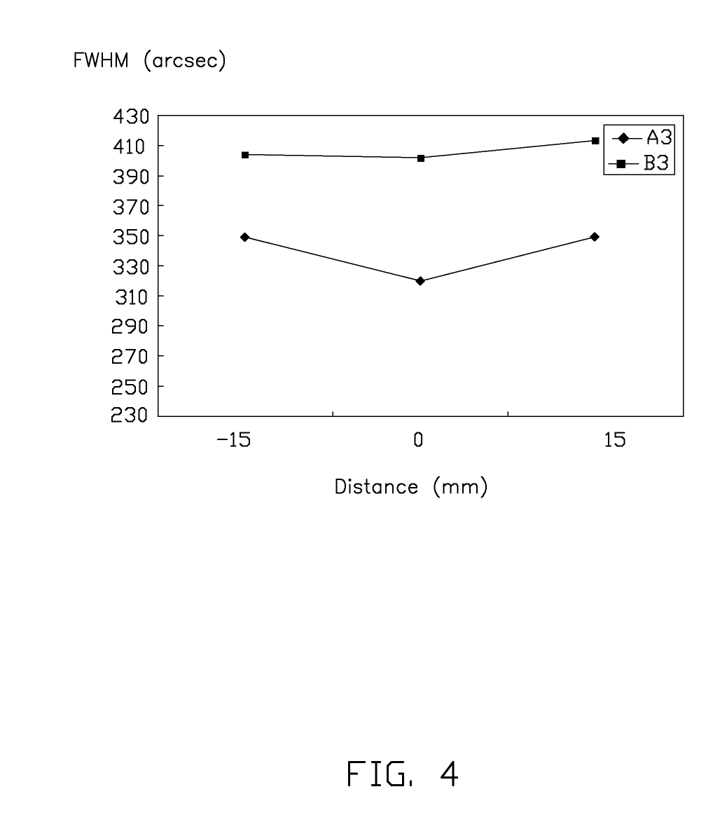

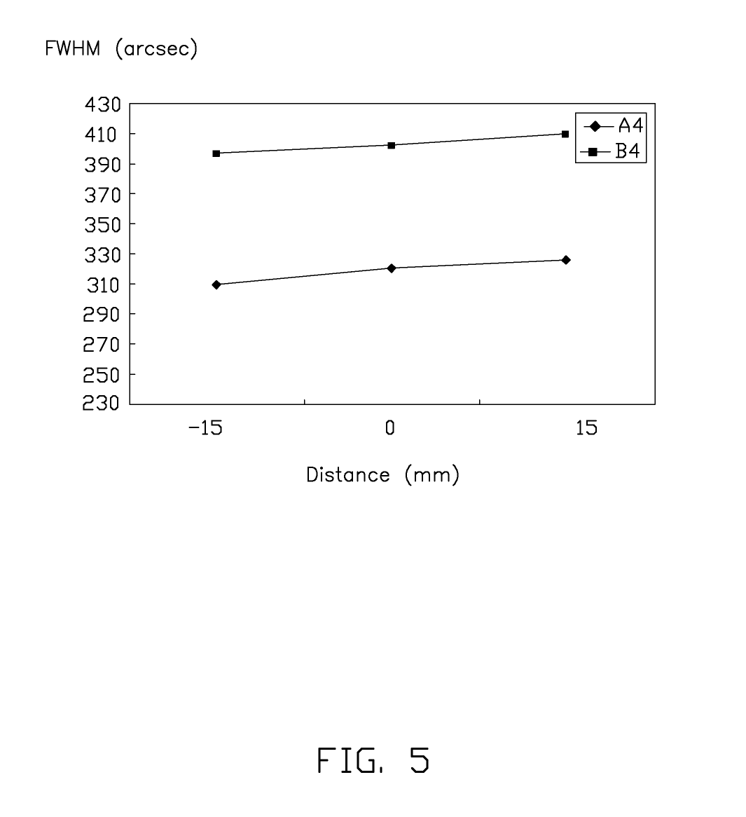

FIGS. 2-5 show full width at half maximum (FWHM) values of an XRD pattern in co-scan of a GaN layer grown from a sapphire substrate. Vertical coordinates represent FWHM values in the XRD pattern in co-scan of the GaN layer. Horizontal coordinates represent distances from a centre position of the GaN layer. When the horizontal ordinate is 0, the FWHM value is measured in the centre position of the GaN layer. When the horizontal ordinate is 15, the FWHM value is measured in a right position 15 mm away from the centre position of the GaN layer. When the horizontal ordinate is −15, the FWHM value is measured in a left position 15 mm away from the centre position of the GaN layer. FIG. 2 shows full width at half maximum (FWHM) values of an XRD pattern of co-scan in (1-100) plane of a GaN layer grown from (002) plane of a sapphire substrate. A1 represents the GaN layer is grown from the sapphire substrate covered by carbon nano-tubes, and B1 represent the GaN layer is grown from the sapphire substrate without being covered by the carbon nano-tubes. As shown in FIG. 2, no matter in the centre position or in the right position 15 mm away from the centre position or in the left position 15 mm away from the centre position of the GaN layer, the FWHM values of the GaN layer grown from the sapphire substrate covered by the carbon nano-tubes are less than the FWHM values of the GaN layer grown from the sapphire substrate without being covered by the carbon nano-tubes. FIG. 3 shows full width at half maximum (FWHM) values of an XRD pattern of co-scan in (11-20) plane of a GaN layer grown from (002) plane of a sapphire substrate. FIG. 4 shows full width at half maximum (FWHM) values of an XRD pattern of co-scan in (1-100) plane of a GaN layer grown from (102) plane of a sapphire substrate. FIG. 5 shows full width at half maximum (FWHM) values of an XRD pattern of co-scan in (11-20) plane of a GaN layer grown from (102) plane of a sapphire substrate. A2, A3, A4 represent FWHM values of the GaN layer grown from the sapphire substrate covered by carbon nano-tubes, and B2, B3, B4 represent FWHM values of the GaN layer grown from the sapphire substrate without being covered by the carbon nano-tubes. Similarly, in FIGS. 3-5, the FWHM values of the GaN layer grown from the sapphire substrate covered by the carbon nano-tubes are less than the FWHM values of the GaN layer grown from the sapphire substrate without being covered by the carbon nano-tubes. The FWHM values of the GaN layer have a relationship with the lattice quality of the GaN layer. The less of the FWHM values of the GaN layer are, the better the lattice quality of the GaN layer will be. Therefore, the lattice quality of the GaN layer grown from the sapphire substrate covered by the carbon nano-tubes is better than the lattice quantity of the GaN layer grown from the sapphire substrate without being covered by the carbon nano-tubes.

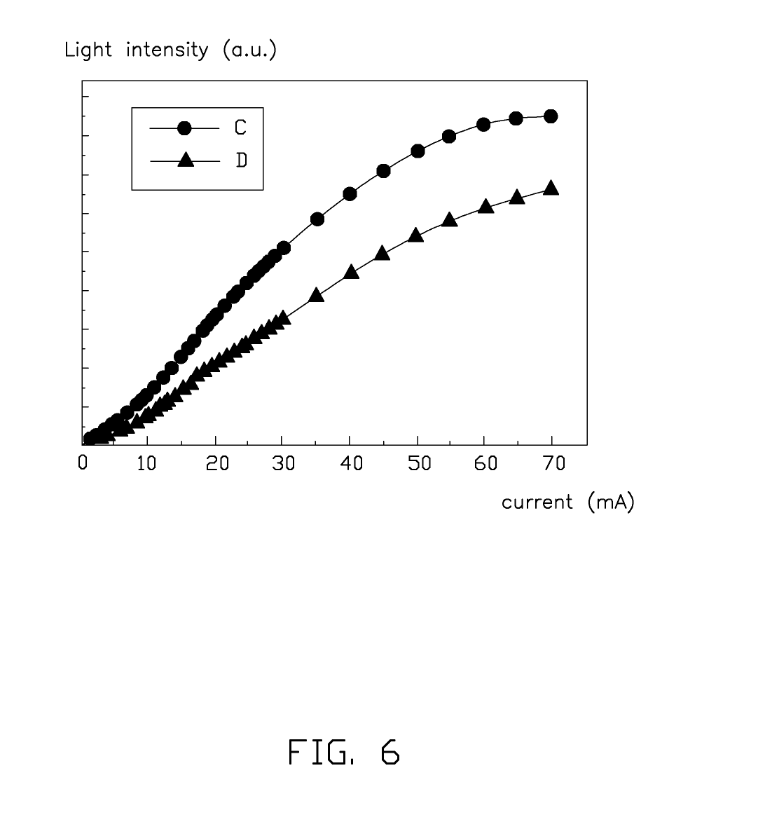

FIG. 6 is a diagraph showing a relationship between a light intensity and a current in the LED epi layer in FIG. 1 being made a chip. C represents the LED chip is grown from a sapphire substrate covered by the carbon nano-tubes. D represents the LED chip is grown from a sapphire substrate without being covered by the carbon nano-tubes. As shown from FIG. 6, when applied with a same current, the light intensity of the LED chip grown from the sapphire substrate covered by the carbon nano-tubes is larger than the light intensity of the LED chip grown from the sapphire substrate without being covered by the carbon nano-tubes.

A method for growing the LED epi layer 100 is also provided. The method includes following steps.

A sapphire substrate 110 is provided.

A plurality of carbon nano-tubes 120 is brought to be located on and cover an upper surface of the sapphire substrate 110. Gaps 121 are formed between two adjacent carbon nano-tubes 120 to expose parts of the upper surface of the sapphire substrate 110. In this embodiment, diameters of the carbon nano-tubes 120 each are in a range from 15 nm to 30 nm. The carbon nano-tubes 120 are parallel to each other and parallel to the upper surface of the sapphire substrate 111.

An un-doped GaN layer 130 is grown from the parts of the upper surface of the sapphire substrate 111 which are not covered by the carbon nano-tubes 120 until the un-doped GaN layer 130 covers the carbon nano-tubes 120. That is, the un-doped GaN layer 130 firstly grows from the gaps 121 between the carbon nano-tubes 120 and then laterally grows to cover the carbon nano-tubes 120.

An n-type GaN layer 140, an active layer 150 and a p-type GaN layer 160 are grown on the un-doped GaN layer 130 in sequence. In this embodiment, the active layer 150 is a multiple quantum wells (MQW) structure.

In the method for growing LED epi layer 100 described above, the lateral growth of the un-doped GaN layer 130 will reduce the lattice defects in the un-doped GaN layer 130, thereby improving epitaxial quality of the n-type GaN layer 140, the active layer 150 and the p-type GaN layer 160 formed on the un-doped GaN layer 130.

It is to be further understood that even though numerous characteristics and advantages of the present embodiments have been set forth in the foregoing description, together with details of the structures and functions of the embodiments, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A light emitting diode epi layer, comprising:
a sapphire substrate;
a plurality of carbon nano-tubes arranged on an upper surface of the sapphire substrate, gaps formed between two adjacent carbon nano-tubes to expose parts of the upper surface of the sapphire substrate;
an un-doped GaN layer, formed on the exposed parts of the upper surface of the sapphire substrate and covering the carbon nano-tubes; and
an n-type GaN layer, an active layer and a p-type GaN layer formed on the un-doped GaN layer in sequence.

2. The light emitting diode epi layer of claim 1, wherein diameters of the plurality of carbon nano-tubes each are in a range from 15 nm to 30 nm.

3. The light emitting diode epi layer of claim 1, wherein the plurality of carbon nano-tubes are parallel to each other.

4. The light emitting diode epi layer of claim 3, wherein the plurality of carbon nano-tubes are parallel to the upper surface of the sapphire substrate.

5. The light emitting diode chip of claim 1, wherein the active layer is a multiple quantum wells (MQW) structure.

6. A method for growing a light emitting diode epi layer, comprising following steps:
providing a sapphire substrate;
arranging a plurality of carbon nano-tubes on an upper surface of the sapphire substrate, wherein every two adjacent carbon nano-tubes are spaced from each other with a gap therebetween, thereby exposing parts of the upper surface of the sapphire substrate via the carbon nano-tubes;
forming an un-doped GaN layer on the exposed parts of the upper surface of the sapphire substrate until the un-doped GaN layer covering the carbon nano-tubes; and
forming an n-type GaN layer, an active layer and a p-type GaN layer on the un-doped GaN layer in sequence.

7. The method of growing a light emitting diode epi layer of claim 6, wherein diameters of the plurality of carbon nano-tubes each are in a range from 15 nm to 30 nm.

8. The method of growing a light emitting diode epi layer of claim 6, wherein the plurality of carbon nano-tubes are parallel to each other.

9. The method of growing a light emitting diode epi layer of claim 8, wherein the plurality of carbon nano-tubes are parallel to the upper surface of the sapphire substrate.

10. The method of growing a light emitting diode epi layer of claim 6, wherein the active layer is a multiple quantum wells (MQW) structure.

11. A method for growing a light emitting diode epi layer, comprising following steps:
providing a sapphire substrate;
arranging a plurality of carbon nano-tubes on an upper surface of the sapphire substrate, wherein gaps are defined among the carbon nano-tubes to expose parts of the upper surface of the sapphire substrate via the carbon nano-tubes;
forming an un-doped GaN layer on the gaps between the carbon nano-tubes until the un-doped GaN layer being laterally grown to cover the carbon nano-tubes; and
forming an n-type GaN layer, an active layer and a p-type GaN layer on the un-doped GaN layer in sequence.

12. The method for growing a light emitting diode epi layer of claim 11, wherein diameters of the plurality of carbon nano-tubes each are in a range from 15 nm to 30 nm.

13. The method for growing a light emitting diode epi layer of claim 11, wherein the plurality of carbon nano-tubes are parallel to each other.

14. The method for growing a light emitting diode epi layer of claim 13, wherein the plurality of carbon nano-tubes are parallel to the upper surface of the sapphire substrate.

15. The method for growing a light emitting diode epi layer of claim 11, wherein the active layer is a multiple quantum wells (MQW) structure.
